(19) United States
(12) Patent Application Publication
(10) Pub. No.: US 2003/0112585 A1
(43) Pub. Date: Jun. 19, 2003

(54) Multiprocessor notebook computer with a tablet PC conversion capability

(76) Inventor: Kelan Craig Silvester, Portland, OR (US)

Correspondence Address: BLAKELY, SOKOLOFF,, TAYLOR & ZAFMAN LLP, Seventh Floor, 12400 Wilshire Boulevard, Los Angeles, CA, 90025-1026, US

(21) Appl. No.: 10/020,717

(22) Filed: Dec. 13, 2001

(51) Int. Cl. G06F 9/00; G06F 9/24; G06F 15/177; H05K 5/00; H05K 7/00

(52) U.S. Cl. 361/679; 713/1

(57) ABSTRACT

An apparatus for a multiprocessor notebook computer with a tablet personal computer (PC) conversion capability. The apparatus of one embodiment comprises a first computer comprising a first processor housed in a first case, the first processor to execute a first set of instructions. A second computer comprises a second processor housed in a second case, the second processor to execute a second set of instructions. A docking connector is coupled to the first case and the second case. The docking connector to mate the first computer and the second computer together. The docking connector to propagate electrical signals between the first processor and the second processor when the first case is physically docked to the second case. The first computer and the second computer operate together as a multiprocessor computer system when the first computer and the second computer are mated. The first computer and the second computer operate as separate computers when the first computer and the second computer are not mated.

### FIELD OF THE INVENTION

The present invention relates generally to the field of computer systems. More particularly, the present invention relates to a method and apparatus for a multiprocessor notebook computer with a tablet personal computer (PC) conversion capability.

### BACKGROUND OF THE INVENTION

Computer systems have become increasingly pervasive in our society. The processing capabilities of computers have increased the efficiency and productivity of workers in a wide spectrum of professions. As the costs of purchasing and owning a computer continues to drop, more and more consumers have been able to take advantage of newer and faster machines. Furthermore, many people enjoy the use of notebook computers because of the freedom. Mobile computers allow users to easily transport their data and work with them as they leave the office or travel. This scenario is quite familiar with marketing staff, corporate executives, and even students.

Despite the physical dimensions of existing notebook computers, there is interest in the market for computing devices with even thriftier form factors. For instance, personal digital assistants and cellular phones with calendar functions are growing in popularity. However, the computing power and capabilities of such devices are somewhat limited. A user is still required to lug a notebook system around even though not all such functionality is necessary at all times. Similarly, the present mobile computers generally include low power microprocessors and accompanying components. The tradeoff for such power savings is often the available horsepower. This can also prevent a user from running some heavy tasks or applications on a mobile computer. Even though current electronic tools provide the freedom and mobility of a traveling office, the technology continues to evolve.

Some notebooks with docking station capabilities exist currently for use at the desk. However, these docking stations provide expansion ports for additional devices not normally contained within the computer housing. But when the notebook is disconnected from the docking station, all of the functions and capabilities of the docking base are no longer available to the notebook. Similarly, the processing capabilities of the notebook computer are not available to the docking base when disconnected.

### BRIEF DESCRIPTION OF THE DRAWINGS

The present invention is illustrated by way of example and not limitations in the figures of the accompanying drawings, in which like references indicate similar elements, and in which:

FIG. 1A is an illustration of a multiprocessor computer system having a capability to separate into a tablet PC and a server PC in accordance with the present invention in its mated state;

FIG. 1B is an illustration of the multiprocessor computer system of FIG. 1A in its detached mode;

FIG. 2 is a block diagram of components located within an embodiment of a convertible dual processor computer system;

FIG. 3 is a block diagram of another embodiment of a dual processor mobile computer system that can detach into separate computing devices;

FIG. 4 is a flow chart showing one embodiment of a method to initialize a convertible dual processor computer in accordance with the present invention.

### DETAILED DESCRIPTION

A method and apparatus for a multiprocessor notebook computer with a tablet personal computer (PC) conversion capability is disclosed. The embodiments described herein are described in the context of a mobile computer, but are not so limited. Although the following embodiments are described with reference to a notebook computer system, other embodiments are applicable to other portable computing devices and other handheld electronic devices. The same techniques and teachings of the present invention can easily be applied to other types of devices or systems that can benefit from a multiprocessor notebook computer with tablet PC conversion capability.

In the following description, for purposes of explanation, numerous specific details are set forth in order to provide a thorough understanding of the present invention. One of ordinary skill in the art, however, will appreciate that these specific details are not necessary in order to practice the present invention. In other instances, well known electrical structures and circuits have not been set forth in particular detail in order to not necessarily obscure the present invention.

Embodiments of the present invention can provide an enhanced notebook computing model. Superior performance can be obtained with a dual processor convertible computer system while still providing a power efficient mobile solution. The system can take advantage of present day operating systems and software applications that users desire. Furthermore, the multiprocessor capabilities of such as system also provides an avenue to future software packages that require greater processing power than that available in existing single processor notebook machines. Implementation of the present invention can allow for flexibility in terms of compute capability and power consumption without sacrificing horsepower or functionality.

This computer system is actually two computers attached together. The notebook system of one embodiment has a convertible tablet top half containing some redundant components to those in the bottom half. Depending on the particular implementation, the two computers, through the use of hardware and/or software, are capable of utilizing resources in both halves of the system like a distributed processing system. A system in accordance with the present invention is a multiprocessor mobile device that can take advantage of distributed processing and secondary resources when the two halves are connected, but can also work independently when the tablet portion is detached from the base module. For one embodiment, the model comprises of two logical computers wherein the lower half with high performance processor becomes a server, while the upper half becomes a client computer. The operating systems and software running independently yet cooperatively in each half of the system are able to take advantage of both processors in the system when the units are connected into single notebook system. The tablet PC portion of the system is a fully functional, portable computing device when detached.

A computer system having a notebook form factor can be configured to include a detachable display which converts into a tablet PC. Each half of the notebook system contains a virtually full feature computer wherein each half can leverage the other half when connected in a distributed computing model. The upper display portion of the system may contain enough complimentary computer components such that it looks like a totally complete computer. Both halves of the convertible notebook system would have its own processor, memory, data storage, etc. For this embodiment, when the upper half of the notebook is detached, this upper half takes control of its display screen. But in normal connected mode, the upper half defers all screen management and display input to the lower portion of the notebook unit. In the detached mode, the upper half acts as a tablet PC, while the lower half can operate as a functional server and to provide additional computing functions available to the upper half. In another embodiment, components may only reside in the portion of the system that makes the most sense. In the case of the graphics controller, it may make sense to provide duplicate graphics controllers wherein the one in the base unit has more capabilities with higher power consumption, while the graphics controller in the upper half of the system is tailored for battery operation using less power. It is possible to include only one graphics controller in the tablet portion of the system which is controlled in docked mode by software running in the base portion of the system.

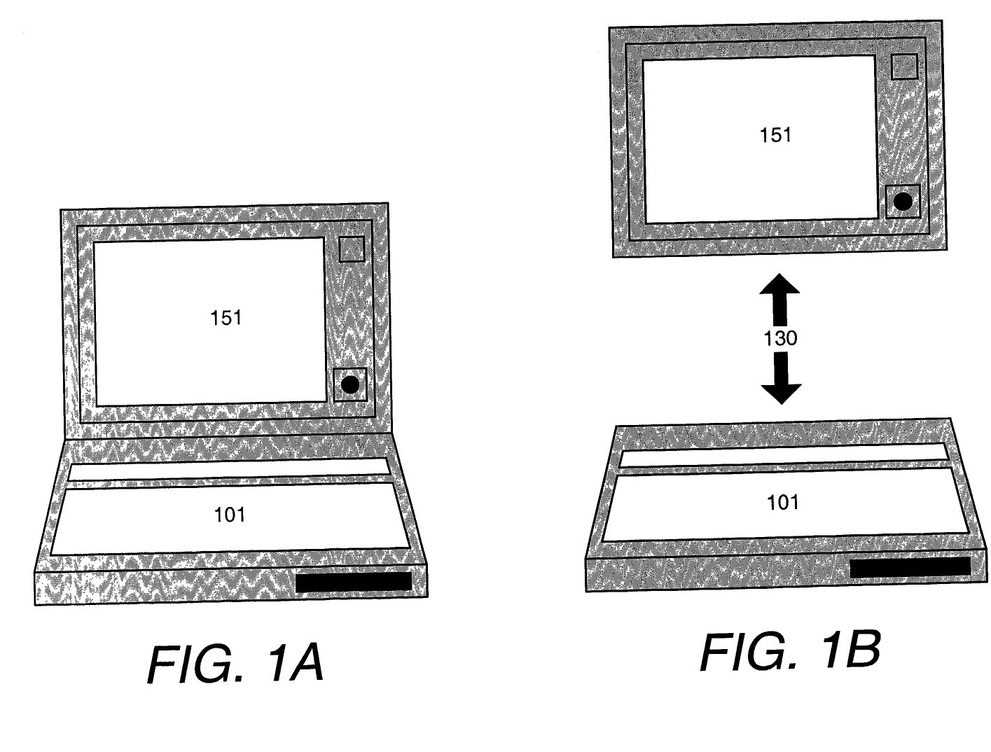

FIG. 1A is an illustration of a multiprocessor computer system having a capability to separate into a tablet PC 151 and a server computer 101 in accordance with the present invention in its mated state. In the mated mode, the system appears as a mobile notebook computer. The system of this embodiment has multiprocessing capability due to a first processor located in the first computer underneath the keyboard of the notebook and a second processor located beneath the display screen. The notebook system may be used as a portable machine or connected to a network, where the system can access other computers or even perform as a server.

FIG. 1B is an illustration of the multiprocessor computer system of FIG. 1A in its detached mode. The notebook system of this embodiment can be separated 130 into two individual computers 101, 151, each having full processing capability. The first computer is a base computer 101 that can function as a server machine if connected to a network. The second computer is a thin, lightweight tablet PC 151 that a user can easily carry around and use when large, unwieldy peripherals such a keyboard or disk drive are not convenient. This tablet PC 151 offers size and weight advantages where it is inconvenient to carry around a notebook machine. The base computer 101 and the tablet PC 151 are also capable of wireless communication with each other for the sharing and access of data and resources. The two halves of the notebook system can be treated as two totally independent computers by the operating environment. Even though they are packaged into the same package, both halves of the system run an operating system software intended for the distributed computing environment. In its normal mode wherein both halves of the computer are together, the primary processor downloads tasks to the secondary processor. In the detached mode of operation depicted in FIG. 1B, user input is through a touch screen/pen input interface of the screen itself. In the connected mode shown in FIG. 1A, user input is through the keyboard as well as through the touch screen.

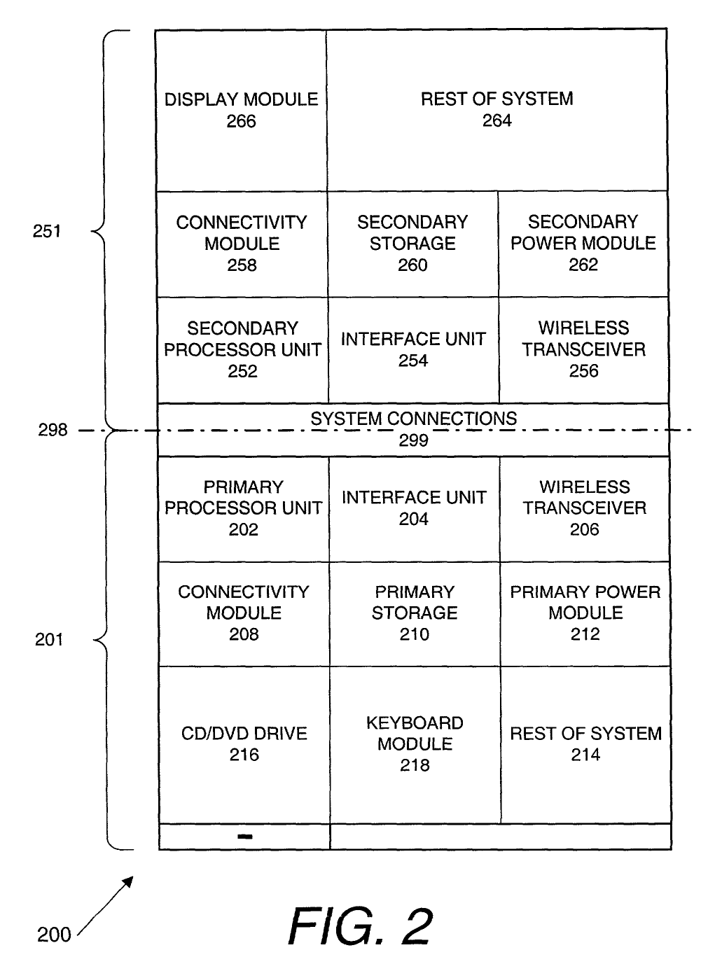

FIG. 2 is a block diagram of components located within an embodiment of a convertible dual processor computer system 200. For this embodiment, the computer system 200 is configured like a mobile notebook computer having clamshell design. The clamshell is formed with a display screen top portion 251 and a keyboard bottom portion 201. The top and bottom portions are connected together at a hinge type mechanism at segment 298. A connection bus at this hinge 298 can provide electrical connectivity between the two halves of the system and to allow for communications and synchronization. For this embodiment, the hinge apparatus has a multi-pin docking connector. The system 200 can be closed and folded up by shutting the top portion over the bottom portion 201. Unlike typical notebook computers, the dual processor system of this embodiment can be converted into two individual stand-alone computers upon separation at mating line 298. For example, the bottom portion 201 of the system 200 is a full function mobile computer wherein the various parts and components of the computer are located within the base of system under the keyboard. The top portion 251 of the system 200 is a tablet computer wherein its various parts and components are located within the lid of the system underneath the display screen.

The base computer 201 in the bottom portion of the notebook system 200 is the primary computer in this embodiment. A primary processor unit 202, primary data storage 210, CD/DVD drive 216, and a keyboard module 218 are in the bottom portion 201 of the system 200. The keyboard module 218 controls the keyboard located on top of these components. A connectivity module 208 in the base computer 201 is to provide external ports and connectors for receiving cables from external devices. The wireless transceiver 206 is to send and receive wireless transmissions to/from the base computer 201. For instance, the wireless transceiver 206 is used to communicate with the tablet PC 251 when the two portions are detached from each other. The wireless transceivers also provides a user with the ability to form a wireless connection between the two halves of the system such that the tablet portion of the computer can be detached for laptop use while the lower portion is stored in a briefcase or on a desk. Furthermore, the two portions can continue to be networked together via the wireless link so that the primary computer can distribute tasks to the other computer. The primary power module 212 is to provide power to the base computer 201 when connected a wall outlet. The primary power module 212 also controls a rechargeable battery mechanism for the base portion 201. An interface unit 204 is to handle the communications between the bottom base computer 201 and the top tablet computer 251 when the two portions are physically mated together.

The tablet computer 251 in the top portion of the notebook system 200 is the secondary computer in this embodiment. A secondary processor unit 252, secondary data storage 260, and a display module 266 are in the top portion 251 of the system 200. The display module 266 controls the display screen located on top of these components. A connectivity module 258 in the tablet PC 251 is to provide external ports and connectors for receiving cables from external devices. The wireless transceiver 256 is to send and receive wireless transmissions to/from the tablet PC 251. The secondary power module 212 is to provide power to the components in the tablet PC 201. For one embodiment, the tablet PC 251 can be connected a wall outlet. The tablet PC 251 can also receive power through system connections 299 when the tablet PC 251 is physically mated with the base computer 201. The secondary power module 262 also includes a rechargeable battery mechanism to power the tablet PC 251 when is unmated and away from the base computer 201. An interface unit 254 is to handle the interaction between the bottom base computer 201 and the top tablet computer 251 when the two portions are physically mated together.

A system connections module 299 is to mate the top portion 251 and the bottom portions 201. System connections is to also provide connectivity of data signals and power busing between the computers. The elements of the computer 201, 251, perform their conventional functions well known in the art. Depending on the particular implementations, the rest of the systems 214, 264, can include various other computer components and peripherals. Similarly, the functionality and form factors of the components in the bottom portion 201 and the top portion 251 may differ even though similar names are used. For the embodiment of FIG. 2, the base computer 201 is assigned as the primary computer or master for the system 200. Thus the requests and tasks of base computer 201 may be have higher priority that those of the tablet PC 251. When the computers are detached, the master 201 can be requested to provide host services such as network access, CD/DVD drive reads, etc. for the tablet PC 251. Furthermore, when the computers are attached together, the primary computer 201 may be set to control all the components in the overall combined system 200. Similarly, the system 200 may be configured such that just the primary computer 201 is operating while the secondary computer 251 is idle or off, except for the display module 266. In alternative embodiments, the system can be partitioned in any number of different ways and the actual components residing in the computers can vary and may or may not overlap. Even though the two computers have some redundant components, the operating systems and management software causes the devices in the system to operate in harmony.

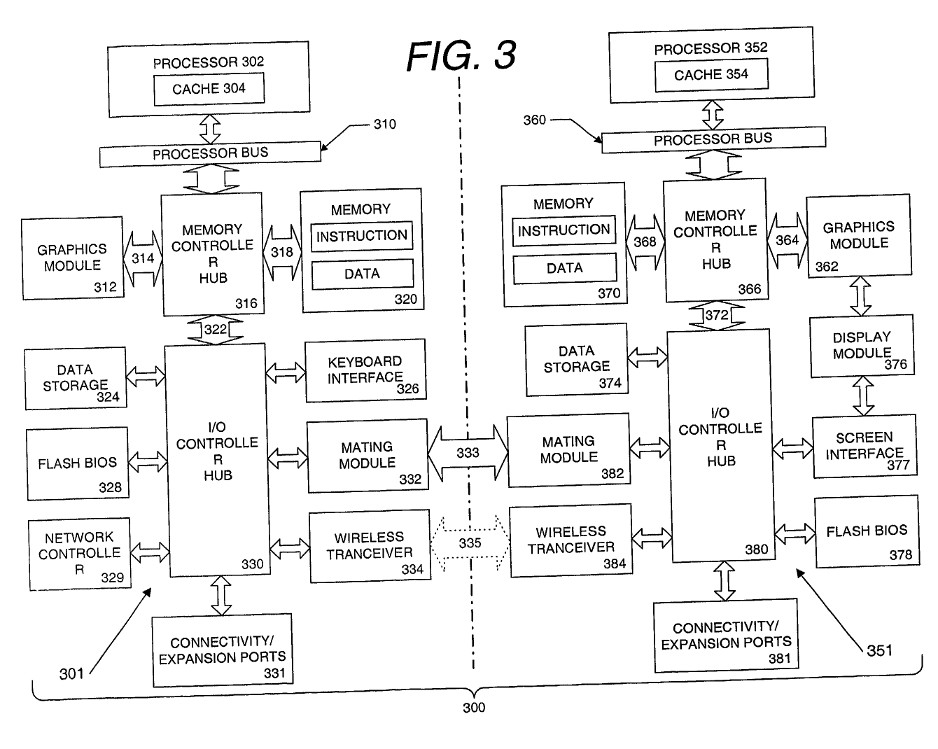

A next generation notebook computer architecture in accordance with the present invention can provide a low power model without the sacrifice of a high performance model when AC power is connected and two halves of the notebook system are connected together. Referring now to FIG. 3, an exemplary multiprocessor computer system 300 is shown. System 300 is representative of processing systems based on the PENTIUM® III, PENTIUM® 4, ITANIUM™ and/or STRONGARM™ microprocessors available from Intel Corporation of Santa Clara, Calif., although other systems (including PCs having other microprocessors, engineering workstations, set-top boxes and the like) may also be used. The computer system 300 of FIG. 3 comprises of two separate computers: a base module computer 301 and a tablet PC 351. In one embodiment, the computers 301, 351, may execute version of the WINDOWS™ operating system available from Microsoft Corporation of Redmond, Wash., although other operating systems and graphical user interfaces, UNIX and LINUX for example, may also be used. Furthermore, the particular operating systems executed on the computers 301, 351, may not be of the same version and/or type. For instance, base computer 301 may execute Microsoft WINDOWS XP or WINDOWS 2000, while tablet PC may execute Microsoft WINDOWS CE or PALM OS® from Palm, Inc. of Santa Clara, Calif. The operating software of the two computers 301, 351, should be compatible or at least able to communicate with each other. A secure data link may also be provided between the machines. Thus, the present invention is not limited to any specific combination of hardware circuitry and software. For this embodiment, software controls the interaction between the computers and the overall system. This software also allows the computers to share and synch data. A security mechanism may be added to either of the devices to prevent unauthorized access to data or use of resources.

FIG. 3 is a block diagram of another embodiment of a convertible dual processor mobile computer system 300 that can detach into separate computing devices 301, 351, in accordance with the present invention. The present embodiment is described in the context of a single processor desktop or server system, but alternative embodiments can be included in a multiprocessor system. Base module computer 301 is an example of a hub architecture. The base computer 301 includes a processor 302 to process data signals. The processor 302 can be a complex instruction set computer (CISC) microprocessor, a reduced instruction set computing (RISC) microprocessor, a very long instruction word (VLIW) microprocessor, a processor implementing a combination of instruction sets, or any other processor device, such as a digital signal processor, for example. The processor 302 is coupled to a processor bus 310 that transmits data signals between the processor 302 and other components in the base computer 301. The elements of base computer 301 perform their conventional functions well known in the art.

Base computer 300 includes a memory 320. Memory 320 can be a dynamic random access memory (DRAM) device, a static random access memory (SRAM) device, flash memory device, or other memory device. Memory 320 can store instructions and/or data represented by data signals that can be executed by the processor 302. An internal cache memory 304 can reside inside the processor 302 to store recently used data signals from memory 320. Alternatively, in another embodiment, the cache memory can reside external to the processor 302.

A system logic chip 316 is coupled to the processor bus 310 and memory 320. The system logic chip 316 in the illustrated embodiment is a memory controller hub (MCH). The processor 302 communicates to the MCH 316 via a processor bus 310. The MCH 316 provides a high bandwidth memory path 318 to memory 320 for instruction and data storage and for storage of graphics commands, data and textures. The MCH 316 is to direct data signals between the processor 302, memory 320, and other components in the base computer 301 and to bridge the data signals between processor bus 310, memory 320, and system I/O 322. In some embodiments, the system logic chip 316 can provide a graphics port for coupling to a graphics controller 312. The MCH 316 is coupled to memory 320 through a memory interface 318. The graphics module 312 is coupled to the MCH 316 through an Accelerated Graphics Port (AGP) interconnect 314.

Base computer 301 uses a proprietary hub interface bus 322 to couple the MCH 316 to the I/O controller hub (ICH) 330. The ICH 330 provides direct connections to some I/O devices via a local I/O bus. The local I/O bus is a high-speed I/O bus for connecting peripherals to the memory 320, chipset, and processor 302. The PCI protocol is commonly associated with a type of the local I/O bus. Some examples are the data storage 324, keyboard interface 326, firmware hub (flash BIOS) 328, and a network controller 329. The data storage device 324 can comprise a hard disk drive, a floppy disk drive, a CD-ROM device, a flash memory device, or other mass storage device.

Base computer also includes a module for connectivity and expansion ports 331 such as Universal Serial Bus (USB) or a parallel port. A mating module 332 and wireless transceiver 334 are coupled to the ICH 330. The mating module 332 of the base computer 301 mates with a corresponding mating module 382 of the tablet PC 351. The mating module 332 is to provide a physical connection 333 between the base computer 301 and the tablet PC 351. When the computers 301, 351, are mated together, the mating module 332 is to handle the sending and receiving of data, instructions, control signals, and power. Similarly, the wireless transceiver 334 of the base computer 301 is to handle the sending and receiving of data and instructions with the wireless transceiver 384 of the tablet PC 351. The wireless transceivers 334, 384, can form a wireless link 335 in accordance with a local area wireless protocol such as the IEEE 802.11a standard, IEEE 802.11b standard, or Bluetooth technology, for example. Wireless link 335 can be one of the standard wireless protocols or a proprietary, non-standard wireless interface. The wireless transceivers 334, 384, are not limited to communications with each other and may also communicate with other wireless devices.

For this embodiment, the tablet PC 351 comprises a similar hub architecture to that of the base computer 301. A processor 352 is coupled to a processor bus 360 to transmit data signals between the processor 352 and other components in the tablet PC 351. MCH 366 couples the processor 352 to memory 370 and tablet PC I/O 372. An ICH 380 is coupled to the MCH 366. The peripheral devices coupled to the ICH of this embodiment includes data storage 374, flash BIOS 378, connectivity and expansion ports 381, mating module 382, and wireless transceiver 384. Even though the components in of the base module computer 301 and tablet PC 351 bear similar names, the exact functionality and form factor may not necessarily be identical. For instance, the components in the tablet PC may be optimized to be lightweight and low power, whereas the components in the base computer may be optimized for higher performance.

A graphics module 362 is coupled to the MCH 366 though AGP interconnect 362. A display module 376 is coupled to receive graphics data from the graphics module 362. A screen interface 377 couples the display module 376 to the ICH 380. The display module 376 of the tablet PC of this embodiment is a lightweight liquid crystal display (LCD) flat-panel display screen. This display module 376 also comprises a touch-sensitive transparent panel covering the LCD screen. The screen interface 377 in this embodiment is to receive user input via the touch screen and to propagate the input data to the processor 352 through the ICH 380.

Although the architectures of the base module computer 301 and the tablet PC 351 are similar, the computers of this embodiment is configured different. For example, the base computer 301 may be optimized for faster performance and network connectivity. The base computer 301 of this embodiment can be connected to a network to perform as a server machine. Thus when the processing capability on the base computer is used, another computer on the network may be able to access this base computer 301 and borrow the computing resources. Similarly, the tablet PC 351 may be optimized for better mobile performance. The tablet PC 351 can be used where full computing functionality such as a keyboard or large display is not needed.

When the base computer 301 and tablet PC 351 of this embodiment are joined together at the mating modules 332, 382, the mated configuration is a multiprocessor notebook computer. The base computer 301, having a keyboard, serves as the bottom half of the notebook clamshell. The tablet PC 351, having a LCD display screen, serves as the top portion of the notebook machine. In this mated mode, a user can set the system 300 to operate with a single processor or with multiple processors. For instance, if high performance or a large amount computing power is needed, the system 300 may be set to operate with both processors 302, 352. The base computer 301 can have a single processor or even multiple processors depending on the performance and power consumption requirements of the particular implementation. But if normal performance or greater power savings is desired, the system 300 may be set to operate with just one of the processors 302, 352. While the base module 301 and tablet PC 351 are physically mated, data can be communicated over the physical link 333 and synchronized. Depending on the particular implementation, the data stored on the two computers 301, 351, may be identical or not. In one embodiment, the tablet PC 351 may be used as a convenient portable digital notepad wherein the user wants to have all the data of the base module 301 available on the tablet PC 351 and any notes taken on the tablet PC 351 available on the base computer 301. Thus the stored data from the base module 301 may be replicated during synchronization with the tablet PC 351 and vice versa. In another embodiment, the data on the base computer 301 and tablet PC 351 may be different and not replicated, but simply shared between the computers 301, 351, when mated together or through wireless communications.

When the base computer 301 and tablet PC 351 are detached, each one has the capability to operate as stand-alone single processor computers. By physically detaching the tabled PC 351 from the base computer 301, the multiprocessor notebook computer system 300 is converted into a separate base module computer 301 and a tablet PC 351. Because the display of the system 300 resides with the tablet PC 351, the base computer 301 is left without a display when in the detached mode. A monitor can be coupled to the graphics module 312 of the base computer 301 if a display is needed. For this example, only one graphics controller 312 or 362 is necessary to operate the display. When both graphics controllers 312, 362, are available in the connected mode of operation, one of the controllers is turned off to reduce power consumption. Similarly, other redundant components within the system may be turned off in the mated mode. In addition to the possible power savings, thermal output can also be reduced. Normally, the detached base computer 301 of one embodiment is left connected to a network to provide network access to the tablet PC 351 and the sharing of computing resources when the base computer 301 is idle or under utilized. In the detached mode, the tablet PC 351 of this embodiment does not have a keyboard or physical network connection. User input is made via a LCD touch screen interface 377 on the tablet PC 351. The wireless transceiver 384 of tablet PC 351 can form a wireless link 335 with the wireless transceiver 334 of the base computer 301 and thus access the network by the network link of the base computer 301.

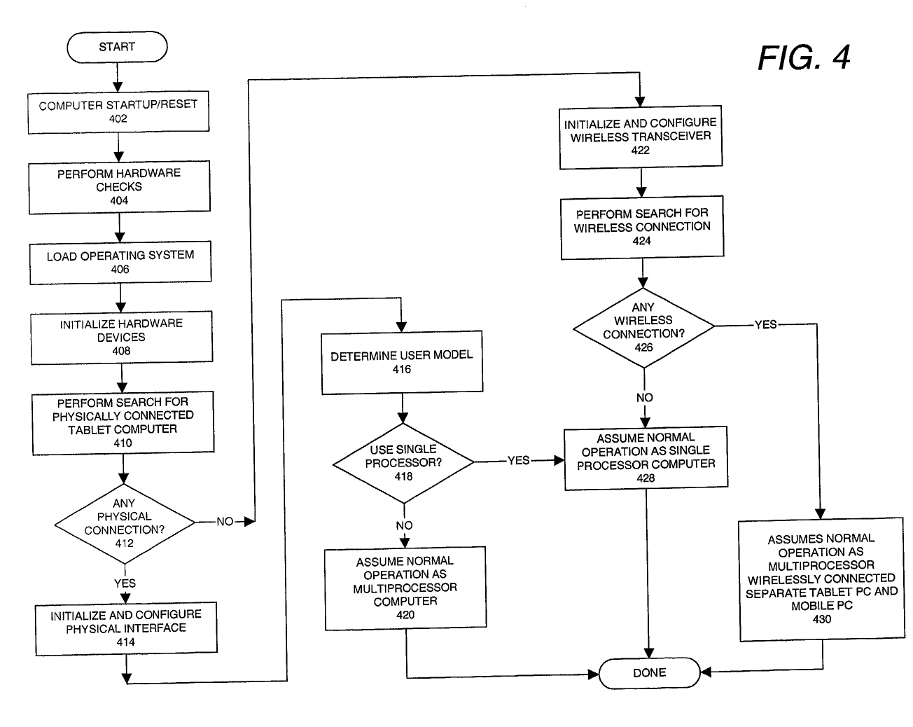

FIG. 4 is a flow chart showing one embodiment of a method to initialize a convertible dual processor computer in accordance with the present invention. This example generally describes the initialization procedure of a base module computer of one embodiment during a system startup or reset. At block 402, the base computer emerges from a system startup or reset sequence. The base computer performs a hardware check of onboard components and devices at 404. This hardware check can entail a query to determine what components and devices are physically present in the base computer and whether they are operational. For this embodiment, these onboard components and devices can include items physically connected to the motherboard like a hard disk drive, floppy drive, CD ROM drive, bus controller, wireless transceiver, and/or video card. The operating system is loaded at block 406. At block 408, the hardware devices found during the hardware checks of block 404 are initialized and configured for use. The base computer performs a search for a physically connected tablet computer at block 410.

At block 412, the base computer checks whether any tablet PC is found physically mated. If a tablet PC is found physically mated with the base computer at block 412, then the base computer initializes and configures the physical interface between the computers at block 414. For one embodiment, the configuration of the physical interface entails a handshaking process between the mating/communication modules. At block 416, the base computer determines what user model is requested. For example, the convertible dual processor notebook computer of this embodiment can operate in at least three different modes: (1) multiprocessor notebook computer with mated base computer and tablet PC; (2) single processor notebook computer with mated base computer and tablet PC; and (3) detached single processor base computer with detached single processor tablet PC. Because the example method of FIG. 4 describes the initialization at the base module computer, block 418 comprises evaluating the user setting at the base computer whether a single processor mode is desired. If a single processor mode is requested, the system assumes normal operation as a single processor computer at block 428. Depending on the particular implementation, either one of the processors available in the system (one in the base computer and one in the tablet PC) may be used in the single processor mode. If a multiprocessor mode is requested at block 418, the system assumes normal operation as a dual processor computer at block 420 with both processor active.

But if no tablet PC is found physically connected at block 412, the wireless transceiver of the base computer is initialized and configured at block 422. The base computer then performs a search for wireless devices in the vicinity at block 424. The wireless device of interest here is the wireless tablet PC. At block 426, a check is made as to whether any wireless connections were detected. If no wireless signal is detected from the tablet PC, the base computer is alone and operates as a stand-alone computer. The system in this instance comprises of the single processor base computer. Thus, the system assumes normal operation as a single processor computer at block 428. If a wireless connection is made with the wireless tablet PC at block 426, the system is operating within the detached single processor base computer and detached single processor tablet PC mode. At block 430, the system assumes normal operations as a multiprocessor system wherein the separate tablet PC and base computer can be in wireless contact. For one embodiment, the detached tablet PC and base computer operate separate from each other and communicate wirelessly when data on the other machine is needed. For an alternate embodiment, the detached tablet PC may continually communicate with the base computer in order to borrow the processor resources or to access an attached network.

In the foregoing specification, the invention has been described with reference to specific exemplary embodiments thereof. It will, however, be evident that various modifications and changes may be made thereof without departing from the broader spirit and scope of the invention as set forth in the appended claims. The specification and drawings are, accordingly, to be regarded in an illustrative rather than a restrictive sense. What is claimed is:

1. A apparatus comprising:
a first computer comprising a first processor housed in a first case, said first processor to execute a first set of instructions;
a second computer comprising a second processor housed in a second case, said second processor to execute a second set of instructions;
a docking connector coupled to said first case and said second case, said docking connector to mate said first computer and said second computer together, said docking connector to propagate electrical signals between said first processor and said second processor when said first case is physically docked to said second case, and
wherein said first computer and said second computer operate together as a multiprocessor computer system when said first computer and said second computer are mated, and wherein said first computer and said second computer operate as separate computers when said first computer and said second computer are not mated.

2. The apparatus of claim 1 wherein said first computer further comprises a first wireless transceiver to send and receive wireless communications.

3. The apparatus of claim 2 wherein said second computer further comprises a second wireless transceiver to send and receive wireless communications.

4. The apparatus of claim 3 wherein said first computer and said second computer communicate together wirelessly when said first computer and said second computer are not mated together.

5. The apparatus of claim 4 wherein said first computer further comprises a keyboard mounted within said first case, said keyboard to receive user input.

6. The apparatus of claim 5 wherein said first computer is a base computer, said base computer to serve as a bottom half of a notebook computer system.

7. The apparatus of claim 6 wherein said second computer further comprises a display screen mounted within said second case, said display screen to output information.

8. The apparatus of claim 7 wherein said second computer is a tablet computer, said tablet computer to serve as a top half of said notebook computer system.

9. The apparatus of claim 8 wherein said first processor is a primary processor for said multiprocessor system when said first computer and said second computer are mated together, and wherein said keyboard and said display screen are controlled by said first processor, said keyboard to send any input received to said first processor and said display screen to display data from said first processor.

10. The apparatus of claim 9 wherein said first computer is coupled to a network, said first computer to operate as a server when said first computer and said second computer are not mated together, and resources of said first computer are available.

11. A mobile computer system comprising:
a tablet personal computer (PC) comprising a liquid crystal display (LCD) screen, a first processor, and a first wireless transceiver;
a base computer module comprising a keyboard, a second processor, and a second wireless transceiver; and
a mating connector to couple together said tablet PC and said base computer module, wherein said tablet PC and said base computer operate together as a multiprocessor computer system while said tablet PC and said base computer module are physically mated, and wherein said tablet PC and said base computer module operate separately as stand-alone computers while said tablet PC and said base computer module are not mated together.

12. The mobile computer system of claim 11 wherein said LCD screen further comprises a touch-sensitive panel covering said LCD screen, said touch-sensitive panel to receive user input.

13. The mobile computer system of claim 12 wherein said tablet PC and said base computer module mate together into a notebook computer form factor, said tablet PC as an upper half of a notebook case and said base computer module as a bottom half of said notebook case.

14. The mobile computer system of claim 13 wherein said first processor and said second processor operate together during a multiprocessor mode to execute instructions and process data.

15. The mobile computer system of claim 14 wherein said tablet PC and said base computer module communicate with each other wirelessly to share data.

16. The mobile computer system of claim 15 wherein said base computer module is coupled to a network, said base computer module to operate as a server machine on said network, and said base computer to further provide network access to said tablet PC.

17. A multiprocessor computing system comprising:
a first computing unit comprising a first processor and a second computing unit comprising a second processor; said first and second computing units designed to mate together to form a singular combined computing unit, wherein said first and second computing units are physically coupled together during a mated mode, and wherein said first and second computing units are not physically coupled together during a detached mode; and
wherein said first and second computing units operate together as a single computer during said mated mode, and said first and second computing units each operate as an individual computer during said detached mode.

18. The multiprocessor computing system of claim 17 wherein said first computing unit is a master and takes primary control of system resources during said mated mode.

19. The multiprocessor computing system of claim 18 wherein said first computing unit further comprises a first wireless transceiver and said second computing unit further comprises a second wireless transceiver, said first and second computing units to communicate via said first and second wireless transceivers to transfer and share data.

20. The multiprocessor computing system of claim 19 wherein said first computing unit is coupled to a network, said first computing unit to provide network access to said second computing unit during said detached mode via wireless communications.
